(19) United States
(12) Patent Application Publication
(10) Pub. No.: US 2025/0343515 A1
(43) Pub. Date: Nov. 6, 2025

(54) AMPLIFIER GAIN SETTLING IMPROVEMENT WITH PRE-BIASING

(71) Applicant: QUALCOMM Incorporated, San Diego, CA (US)

(72) Inventors: Mikko KALTIOKALLIO, Espoo (FI); Tero TIKKA, Espoo (FI); Jouni Kristian KAUKOVUORI, Vantaa (FI)

(21) Appl. No.: 18/653,419

(22) Filed: May 2, 2024

(51) Int. Cl. H03F 1/22; H03F 3/193; H04B 1/40

(52) U.S. Cl. CPC H03F 1/223; H03F 3/193; H04B 1/40; H03F 2200/294; H03F 2200/451

(57) ABSTRACT

Certain aspects are directed towards an amplifier. The amplifier generally includes: a first gain path coupled between an input of the amplifier and an output of the amplifier, wherein the first gain path comprises a first input transistor with a gate coupled to the input of the amplifier; a bypass path selectively coupled between the input of the amplifier and the output of the amplifier and configured to bypass at least the first input transistor of the first gain path in a bypass mode; and a bias circuit configured to bias the first input transistor with a first bias voltage at a level that causes a current to flow between a source and a drain of the first input transistor when the amplifier is in the bypass mode.

### TECHNICAL FIELD

Certain aspects of the present disclosure generally relate to electronic circuits and, more particularly, to techniques for signal amplification.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more amplifiers for amplifying received signals for processing.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include reduced settling time.

Certain aspects are directed towards an amplifier. The amplifier generally includes: a first gain path coupled between an input of the amplifier and an output of the amplifier, wherein the first gain path comprises a first input transistor with a gate coupled to the input of the amplifier; a bypass path selectively coupled between the input of the amplifier and the output of the amplifier and configured to bypass at least the first input transistor of the first gain path in a bypass mode; and a bias circuit configured to bias the first input transistor with a first bias voltage at a level that causes a current to flow between a source and a drain of the first input transistor when the amplifier is in the bypass mode.

Certain aspects are directed towards a method for signal processing. The method generally includes: bypassing one or more gain paths of an amplifier via a bypass path selectively coupled between an input of the amplifier and an output of the amplifier when the amplifier is in a bypass mode, wherein the one or more gain paths include a first gain path coupled to the output of the amplifier and including a first input transistor with a gate coupled to the input of the amplifier; and biasing, via a bias circuit, the first input transistor with a first bias voltage such that a current flows between a source and a drain of the first input transistor when the amplifier is in the bypass mode.

Certain aspects are directed towards a wireless device. The wireless device generally includes an antenna and an amplifier having an input coupled to the antenna, wherein the amplifier comprises: a gain path coupled between the input of the amplifier and an output of the amplifier, wherein the gain path comprises an input transistor with a gate coupled to the input of the amplifier; a bypass path selectively coupled between the input of the amplifier and the output of the amplifier; a bias circuit configured to bias the input transistor; and a control circuit configured to provide one or more control signals to the amplifier that enable the bypass path in a bypass mode and provide a first bias voltage to the input transistor at a level that causes a current to flow between a source and a drain of the input transistor during the bypass mode.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 illustrates an example low-noise amplifier (LNA) configured in an active mode, in accordance with certain aspects of the present disclosure.

FIG. 5 illustrates an example LNA in a bypass mode, in accordance with certain aspects of the present disclosure.

FIG. 6 illustrates an example LNA in a bypass mode with pre-biasing, in accordance with certain aspects of the present disclosure.

FIG. 7 illustrates an example bias circuit, in accordance with certain aspects of the present disclosure.

FIG. 8 illustrates an example direct-input LNA with pre-biasing disabled, in accordance with certain aspects of the present disclosure.

FIG. 9 illustrates an example direct-input LNA with pre-biasing enabled, in accordance with certain aspects of the present disclosure.

FIG. 10 is a flow diagram illustrating example operations for signal amplification, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed toward a low-noise amplifier (LNA) implemented with pre-biasing during a bypass mode. There are stringent gain-switching settling time specifications for LNAs. Measurements have shown that some current technologies have problems when transitioning between gain modes. This is especially problematic when transitioning between a passive gain mode (e.g., bypass mode) and an active gain mode. The LNA is typically turned off in passive gain mode to reduce current consumption. In silicon-on-insulator (SOI) complementary metal-oxide-semiconductor (CMOS) technologies, a floating-body-type transistor may be used for the LNA to improve LNA performance. The potential of the floating body may depend on the current flowing (e.g., drain-to-source current) through the transistor, which creates small currents to the body. When transitioning to the active gain mode, the currents to the body cause the body potential of the transistor to increase and settle slowly to a potential to provide the active mode gain. This slow settling of the body potential may result in gain-switching settling time specifications not being met. Certain aspects provide special biasing conditions in a passive gain mode (e.g., bypass mode) to create a pre-bias condition. With pre-biasing, small currents to the body of the LNA transistor are created to increase the potential of the transistor body. Thus, when the switch from the passive gain mode to the active gain mode occurs, the settling of the LNA gain is faster.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” and “coupled to” in the various tenses of the verb “connect” may mean that element A is directly connected to element B or that other elements may be connected between elements A and B (i.e., that element A is indirectly connected with element B). In the case of electrical components, the term “connected with” and “coupled to” may also be used herein to mean that a wire, trace, or other electrically conductive material is used to electrically connect elements A and B (and any components electrically connected therebetween).

### An Example Wireless System

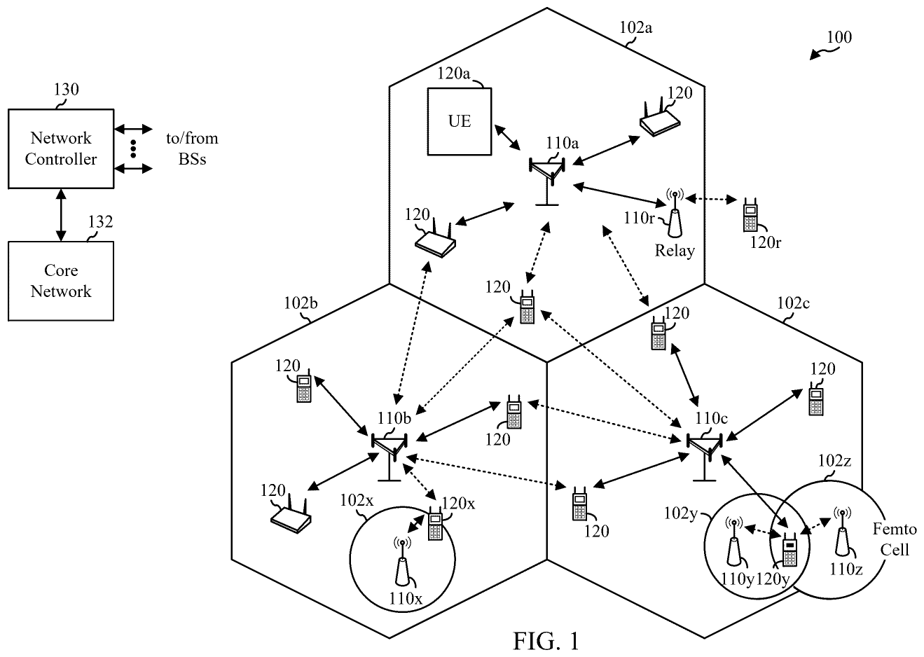

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipment's (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nₐₚ of antennas to achieve transmit diversity for downlink transmissions and/or receive diversity for uplink transmissions. A set Nᵤ of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nᵤ UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include a low-noise amplifier (LNA) implemented with pre-biasing during a bypass mode, as described below.

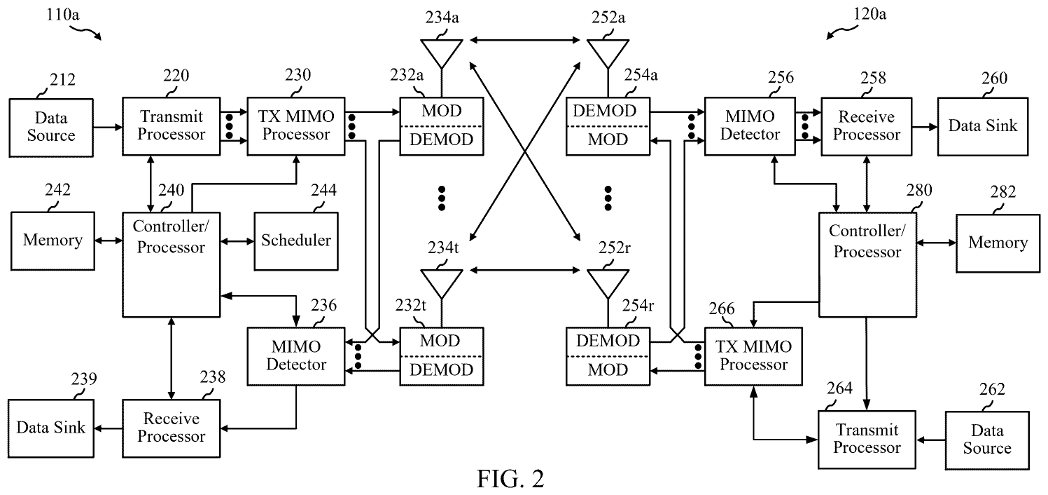

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

In certain aspects of the present disclosure, the transceivers 232 and/or the transceivers 254 may include an LNA implemented with pre-biasing during a bypass mode, as described below.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

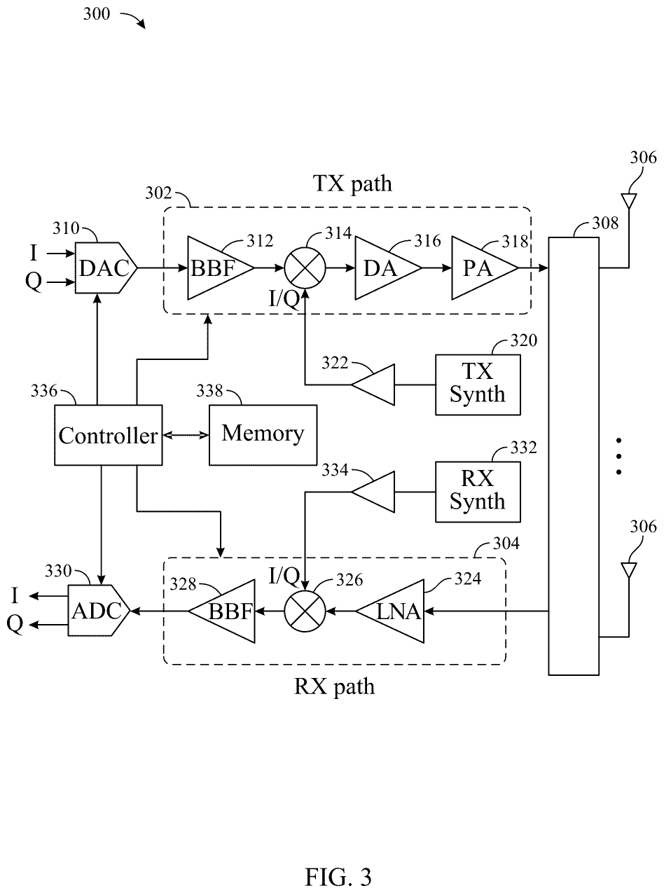

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. In some aspects, the LNA may be implemented with pre-biasing during a bypass mode, as described below. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency divider/multiplier that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

Certain aspects of the present disclosure may be applied for any suitable transceiver architectures. In some implementations, one or more front-end modules or front end components may be included in transmit or receive chains of the transceiver with additional amplifiers. For example, a front-end LNA may be implemented in a receive path external to a transceiver chip, followed by another LNA in the receive path within the transceiver chip. As another example, the transmit chain of the transceiver may include one or more amplifiers such as an additional PA in a front end-module.

While FIGS. 1-3 provide wireless communications as an example application in which certain aspects of the present disclosure may be implemented to facilitate understanding, certain aspects described herein may be used for any of various other suitable systems.

### Example Techniques for Pre-Biasing a Low-Noise Amplifier

In modern radio frequency (RF) front-end modules, multi-gain low-noise amplifiers (LNAs) may be used to satisfy different receive path gain specifications. For example, LNA gain may be adjusted from 21 dB down to −12 dB. Most of the gain states are active in that the LNA is biased and the signal is passed through the input transistor. There are also gain modes where the gain is less than 0 dB, which can be implemented using the active mode or using a passive mode (e.g., also referred to herein as a “bypass mode”) of the LNA. The passive gain mode is implemented with a bypass path over the LNA core, as described in more detail herein. Under normal operations, the LNA dynamically switches between the different gain modes based on modem requests.

When transitioning from one gain to another, the LNA should complete the gain mode transition within a certain time per specification to provide error-free reception. Current multi-gain LNA implementations may not be able to perform gain switching within the time period per specifications. The longest transition time may occur when the LNA transitions from a passive mode (e.g., where the LNA core is bypassed) to an active mode.

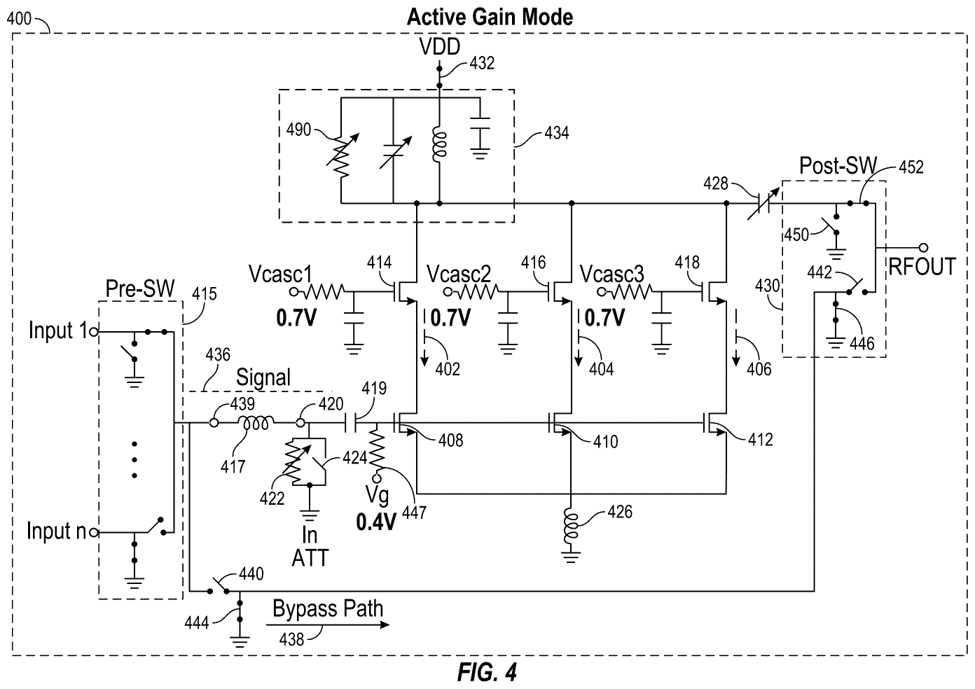

FIG. 4 illustrates a multi-gain LNA 400 configured in active mode, in accordance with certain aspects of the present disclosure. The LNA 400 may include multiple gain paths, such as paths 402, 404, 406. The gain paths 402, 404, 406 include input transistors 408, 410, 412 (also referred to as “transconductance transistors”), respectively. When implemented as n-type metal-oxide semiconductor (NMOS) transistors, the sources of input transistors 408, 410, 412 may be coupled to a reference potential node (e.g., electric ground)-often through an inductive element 426. The different gain paths 402, 404, 406 provide different gain settings for the LNA. Each of the cascode transistors 414, 416, 418 may be biased using a respective cascode voltage (e.g., labeled “Vcasc1,” “Vcasc2,” “Vcasc3”). Using the cascode voltages, one or more of the gain paths 402, 404, 406 may be activated to set the gain of the LNA. Other implementations using different transistor types are possible.

The input transistors 408, 410, 412 may be coupled in cascode with cascode transistors 414, 416, 418, respectively. The drains of cascode transistors 414, 416, 418 are coupled to an output node (labeled “RFOUT”) through a capacitive element 428 and a post-switch (post-SW) circuit 430. As shown, the drains of the cascode transistors 414, 416, 418 may be coupled to a voltage rail (VDD) through a switch 432 and an impedance 434. In active mode, the switch 432 is closed to power the LNA. The impedance 434 may be adjusted to adjust a gain of the LNA 400, in some implementations. For example, the resistance of resistive element 490 may be adjusted to set the gain of the LNA 400.

As shown, a pre-switch (pre-SW) circuit 415 may selectively couple one or multiple inputs (e.g., Input 1 to Input n, n being any positive integer) to gates of input transistors 408, 410, 412 through an inductive element 417 (e.g., a series matching coil) and a capacitive element 419, as shown. The input transistors 408, 410, 412 may be biased using an input transistor gate voltage (Vg). Vg may be provided to the gates of input transistors 408, 410, 412 through a resistive element 447.

Input attenuation may be implemented via a resistive element 422 (e.g., variable resistive element) coupled between node 420 and the reference potential node. The resistance of the resistive element 422 may be adjusted to adjust the gain of the LNA 400, in some aspects. A switch 424 may be coupled in parallel with resistive element 422, where resistive element 422 is effectively bypassed when the switch 424 is closed in bypass mode. The LNA 400 also includes a bypass path 438 including series switches 440, 442 and shunt switches 444, 446. The bypass path 438 may be coupled to a node 439 between an input (e.g., Input 1 to Input n) of the LNA 400 and gate of input transistors 408, 410, 412. In active mode, the switches 444, 446 are closed, and switches 440, 442 are open, as shown. Moreover, the switch circuit 430 includes (i) a series switch 452 between RFOUT and the capacitive element 428 and (ii) shunt switch 450 between switch 452 and the reference potential node. In active mode, switch 452 is closed, and the switch 450 is open. Moreover, in active mode, Vg may be set to 0.4 V to bias the input transistors, and one or more of the cascode voltages (Vcasc1, Vcasc2, and Vcasc3) may be set to 0.7 V to activate one or more of the gain paths 402, 404, 406. While example voltages are provided to facilitate understanding, any suitable voltage levels may be used to bias the input and cascode transistors described herein. In active mode, a received signal (represented by arrow 436) is provided to the gates of the input transistors 408, 410, 412 for amplification.

While the LNAs described herein (e.g., such as the LNA 400 of FIG. 4) are implemented using certain examples of circuits, other suitable circuits may be used. For example, while certain circuits are described for an attenuator (e.g., including resistive element 422), input matching (e.g., including inductive element 417), impedance 434, and degeneration inductive element 426 to facilitate understanding, it should be appreciated that other implementations are possible and applicable to the concepts described herein. For example, there may be different implementations with regard to input matching circuitry, the attenuator (or an implementation without an attenuator), post-SW and pre-SW configurations, the load impedance 434, and the degeneration inductive element 426. In addition, in some implementations, the bypass path may have certain components (e.g., impedance elements or the like) that are not shown.

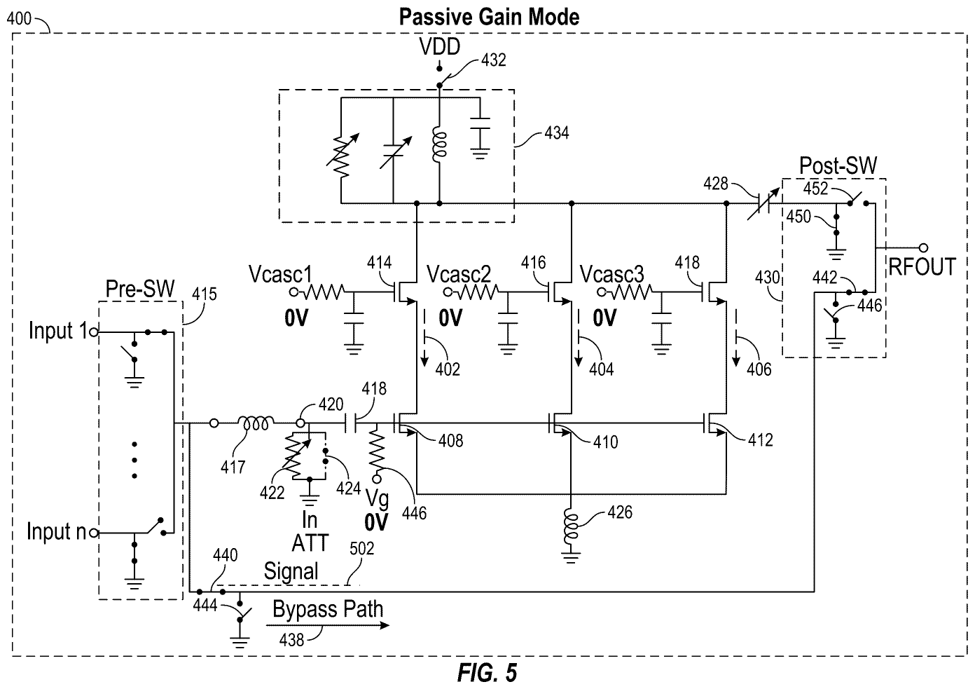

FIG. 5 illustrates the LNA 400 in a bypass mode, in accordance with certain aspects of the present disclosure. As shown, in the bypass mode, series switches 440, 442 and shunt switch 450 are closed, and shunt switches 444, 446 and series switch 452 are open. Thus, the received signal (represented by arrow 502) is provided from the input (e.g., one of inputs 1-n) to RFOUT through the bypass path, as shown. In this case, Vg for biasing the input transistors 408, 410, 412 may be set to 0 V, and the cascode voltages (Vcasc1, Vcasc2, and Vcasc3) may be set to 0 V, as shown. In the bypass mode, the switch 424 may be closed, coupling the node 420 to the reference potential node (electric ground). The switch 432 may be open or closed in bypass mode.

In some cases, the LNA 400 may be unable to meet stringent settling time specifications when switching between gain modes, such as when switching from a bypass mode to an active mode, as described. This may be due to floating-body-type transistors used for the LNA. That is, the body of the input transistors and the cascode transistors may be floating (e.g., not shorted to any other transistor terminal). While using a floating-body-type transistor provides improved RF performance, the body potential of the transistors causes a slow settling time when switching gain settings. The charging and discharging of the body potential may be dependent on the transistor's intrinsic currents and, thus, may be sensitive to temperature and device variations. When a drain current (Id) flows across a transistor (e.g., the input or cascode transistors), small currents flow to the body of the transistor, increasing the body potential. However, the current to the body is small, which slows the settling time of the transistor to set a new gain.

Certain aspects of the present disclosure are directed towards pre-biasing the floating-body-type transistors of the LNA during bypass mode, allowing for a faster settling time when transitioning to active mode. The passive to active gain state settling may be improved by pre-biasing transistors in the passive mode with a small bias current. The small bias current in passive mode pre-biases (e.g., pre-charges) the floating body of the transistors and makes the transition from passive mode to active mode faster.

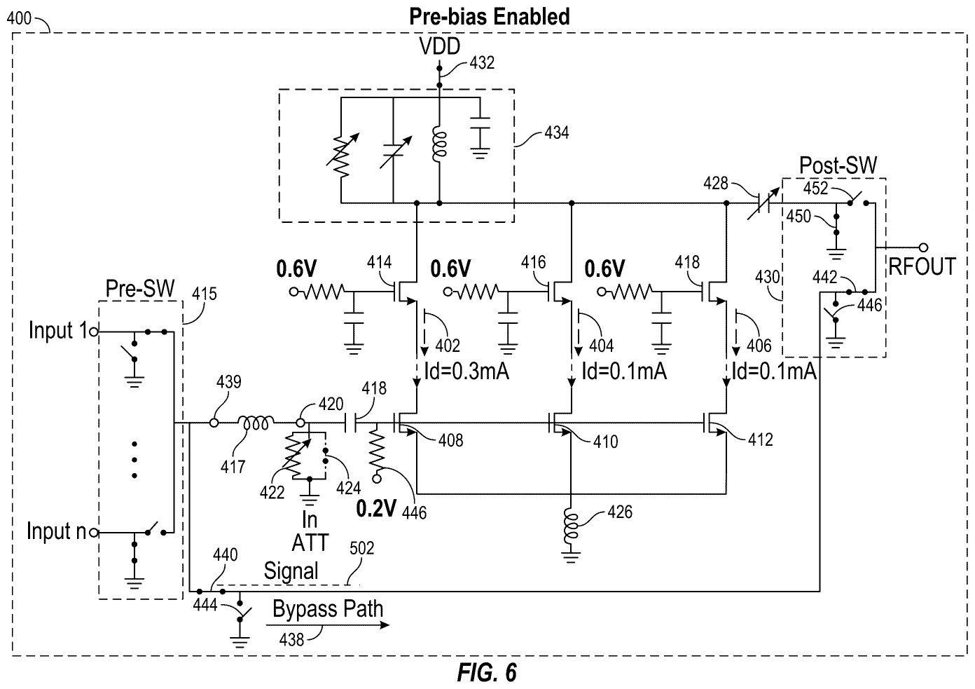

FIG. 6 illustrates the LNA 400 in pre-bias mode (e.g., bypass mode with pre-biasing), in accordance with certain aspects of the present disclosure. The switch 432 may be closed in pre-bias mode. As shown, Vg provided to the gates of input transistors 408, 410, 412 may be set to 0.2 V (e.g., instead of 0 V) in the pre-bias mode (as one example of a bias voltage for a pre-bias mode). Moreover, the cascode voltages (Vcasc1, Vcasc2, and Vcasc3) provided to the gates of the cascode transistors 414, 416, 418 may be set to 0.6 V. Thus, for these example bias voltages, the drain current (Id) of transistor 408 (and transistor 414) may be about 0.3 mA, the Id of transistor 410 (and transistor 416) may be about 0.1 mA, and the Id of transistor 412 (and transistor 418) may be about 0.1 mA. The drain currents charge the body of input transistors 408, 410, 412 and the body of each transistor 414, 416, 418 during the bypass mode. By charging the body of the input transistors 408, 410, 412 and the body of each transistor 414, 416, 418, the settling of the LNA gain may be performed faster once the LNA is switched from the pre-bias mode to the active gain mode. To switch from the pre-bias mode to the active gain mode, Vg may be set to 0.4 V to bias the input transistors, and one or more of the cascode voltages (Vcasc1, Vcasc2, and Vcasc3) may be set to 0.7 V to activate one or more of the gain paths 402, 404, 406.

While the example LNA 400 is implemented with a single cascode transistor for each gain path, any suitable number of cascode transistors may be used. For example, two cascode transistors may be used to increase the isolation between RFOUT and the input of the LNA during active mode. An example LNA with multiple cascode transistors is described in more detail herein. Moreover, while the LNA 400 includes multiple gain paths, any number of gain paths may be used, such as a single gain path.

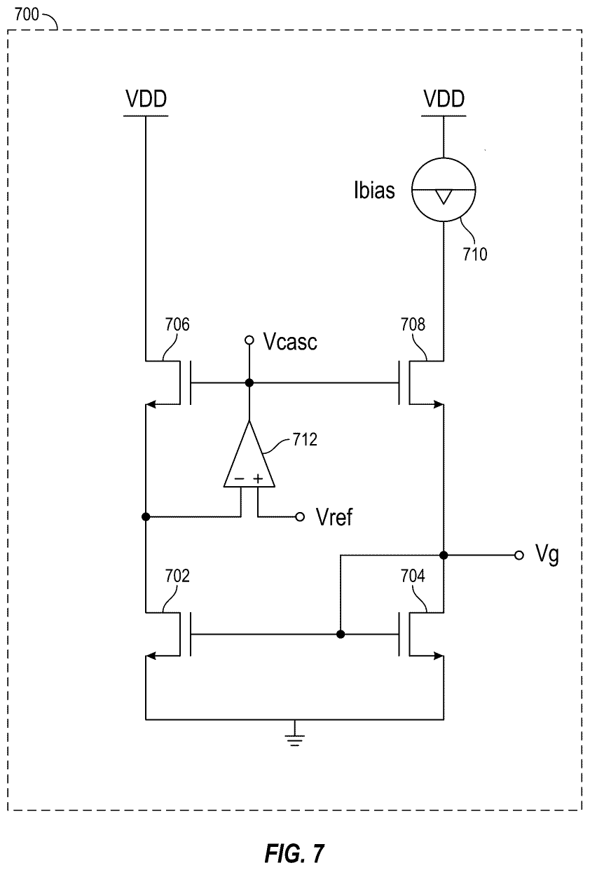

FIG. 7 illustrates an example bias circuit 700, in accordance with certain aspects of the present disclosure. The bias circuit 700 may generate Vg for input transistors 408, 410, 412 and the cascode voltage for each of the cascode transistors 414, 416, 418. In some cases, the same cascode voltage may be used to drive the gates of cascode transistors 414, 416, 418 in the bypass mode for pre-biasing. As shown, the bias circuit 700 may include transistors 702, 704. The sources of transistors 702, 704 may be coupled to a reference potential node. Moreover, the gate of transistor 704 may be coupled to a drain of transistor 704. The transistors 702, 704 form a current mirror.

The bias circuit 700 may also include a current source 710 coupled between a voltage rail VDD and a cascode transistor 708. The cascode transistor 708 may be coupled in cascode with transistor 704 as shown. The bias circuit 700 may also include a cascode transistor 706 coupled in cascode with transistor 702. The current mirror formed by transistors 702, 704 mirrors the current from the current source 710 to generate a mirrored current sunk from the source of cascode transistor 706.

The bias circuit 700 also includes an operational amplifier 712 having a negative input coupled a drain of transistor 702 and a positive input coupled to a reference voltage (Vref) node. An output of the amplifier 712 may be coupled to gates of cascode transistors 706, 708. The output voltage of amplifier 712 may be used as the cascode voltage (Vcasc) for one or more of the cascode transistors (e.g., transistors 414, 416, 418) of the LNA 400. Moreover, the voltage at the drain of transistor 704 may be used as Vg for the input transistors 408, 410, 412. To generate Vg and Vcasc in the bypass mode with pre-biasing, the current source 710 may be configured to provide a bias current (Ibias) (e.g., 20 μA) that is less than Ibias (e.g., 400 μA) provided by current source 710 in active mode.

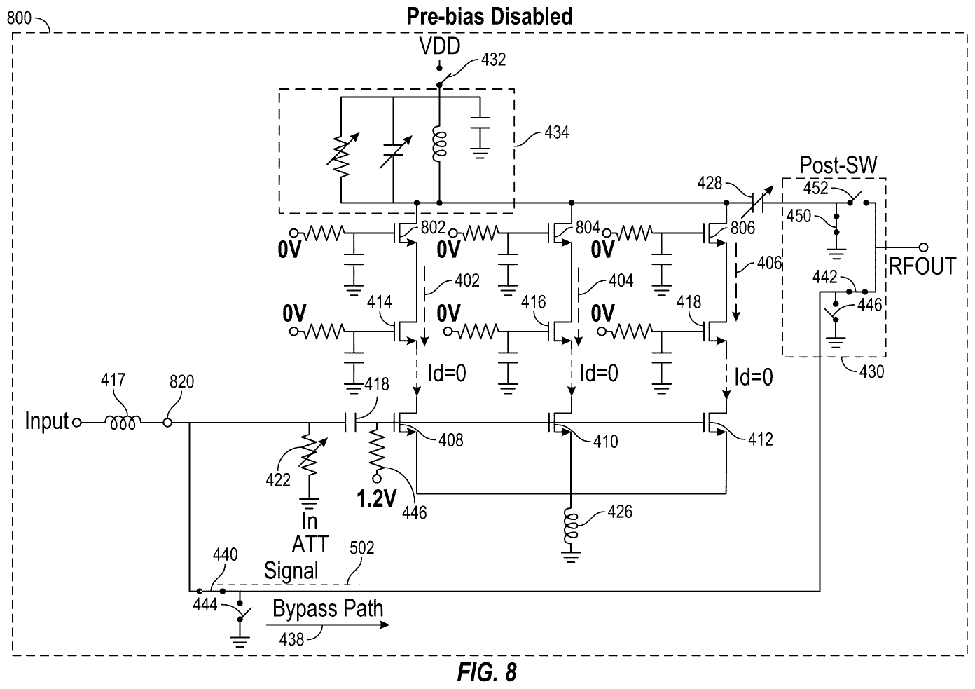

FIG. 8 illustrates a direct-input LNA 800 with pre-biasing disabled, in accordance with certain aspects of the present disclosure. As shown, instead of the inductive element 417 being coupled between the gates of the input transistors and the bypass path, the inductive element 417 is coupled between the input of the LNA 800 and the bypass path. That is, the bypass path is coupled to a node 820 between the inductive element 417 and the gates of the input transistors 408, 410, 412. As a result, in the bypass mode, any non-linearity associated with the capacitance of the input transistors 408, 410, 412 adversely impacts the linearity of the signal through the bypass path. Therefore, in the bypass mode, Vg is used to provide direct current (DC) bias for the input transistors 408, 410, 412 may be set to a higher voltage (e.g., 1.2 V as opposed to 0.2 V for LNA 400 as shown in FIG. 6) so that the input transistors 408, 410, 412 are biased in a more linear region of operation.

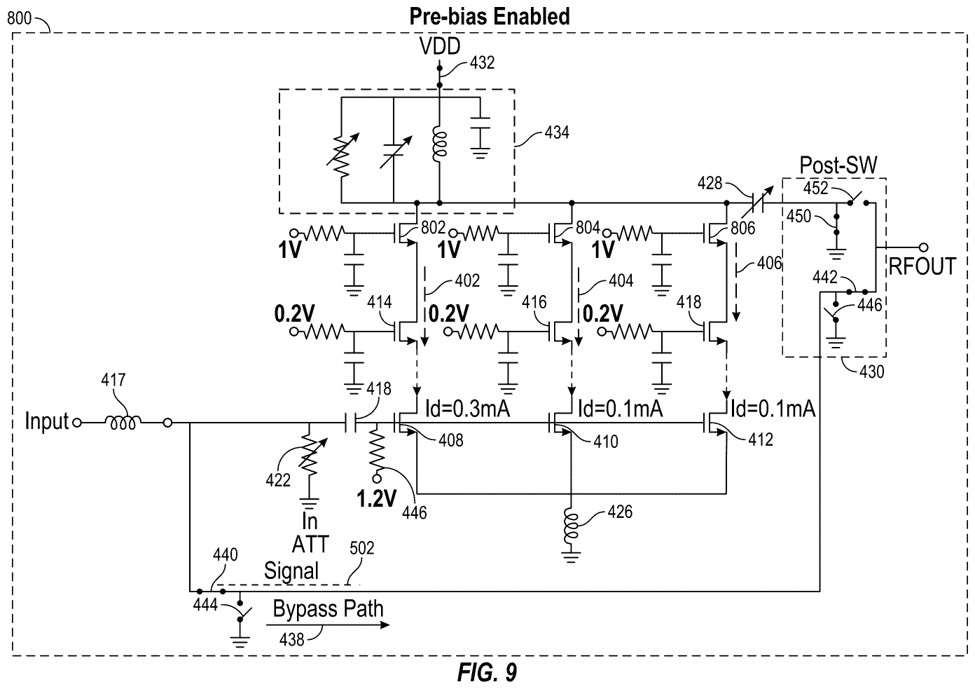

In other words, in a pre-SW LNA (e.g., an LNA including the pre-SW circuit 415) such as the LNA 400 of FIG. 4, the bypass path is connected before the inductive element 417 (e.g., is connected to the LNA input side of the inductive element 417), allowing the use of a pull-down on the other side of the coil by closing switch 424, creating a signal ground and improving performance. In this case, the gate bias point for the input transistors can be freely selected. But for the direct-input LNA 800, the bypass path connection is after the series coil (e.g., is connected to the input transistor side of the inductive element 417). Therefore, a pull-down using switch 424 may not be used. If the same bias point was used for the input transistors for LNA 800 as for LNA 400, the non-linear capacitance of the input transistors would degrade the performance of the LNA 800. Therefore, the bias voltage for input transistor gates may be increased and drain currents of gain paths may be constrained with the biasing of the cascode transistors. By increasing Vg for biasing the input transistors (e.g., to 1.2 V), the linearity performance of the LNA 800 is improved. The bypass current (e.g., Id of gain paths) that improves the settling time may be achieved by slightly increasing the cascode transistor gate voltage (e.g., to 0.2 V) as described in more detail with respect to FIG. 9.

As described herein, in some implementations, multiple cascode transistors may be used for each of the gain paths 402, 404, 406. For example, cascode transistor 802 may be coupled in cascode with cascode transistor 414, cascode transistor 804 may be coupled in cascode with cascode transistor 416, and cascode transistor 806 may be coupled in cascode with cascode transistor 418. With pre-bias disabled, the cascode transistors may be disabled (e.g., biased with 0 V) so that the drain currents (Id) of the input transistors are zero.

FIG. 9 illustrates the LNA 800 with pre-bias enabled, in accordance with certain aspects of the present disclosure. As shown, the cascode transistors 414, 416, 418 may be biased with a low DC bias voltage (e.g., 0.2 V) to set the drain currents (Id) of input transistors 408, 410, 412 to 0.3 mA, 0.1 mA, 0.1 mA, respectively, and charge the bodies of the input and cascode transistors. The gates of cascode transistors 802, 804, 806 may be driven with a higher voltage (e.g., 1.0 V). While two cascode transistors are used for LNA 800, any number of cascode transistors may be used. For example, the LNA 800 may be implemented with a single cascode transistor (e.g., cascode transistors 414, 416, 418) for each gain path. In this case, the gates of cascode transistors 414, 416, 418 may be driven by 0.2 V to set the drain currents of the gain paths for pre-biasing, as shown.

While certain example bias voltages are described for pre-biasing the LNA to facilitate understanding, aspects of the present disclosure may be implemented using any suitable bias voltages. For example, the input transistors 408, 410, 412 and the cascode transistors 414, 416, 418 may be biased using a higher voltage as described to increase the drain currents on the gain paths. Increasing drain currents results in higher power consumption for the LNA, but also provides faster settling when transitioning from bypass mode to active mode. Thus, the bias voltages for pre-biasing may be selected based on a tradeoff between power consumption and settling time.

Certain aspects of the present disclosure improve the settling time of the LNA when transitioning from bypass mode to active mode. Moreover, the distribution of the settling time is also improved. In other words, with the pre-biasing, the amount of variation in the settling time may be decreased.

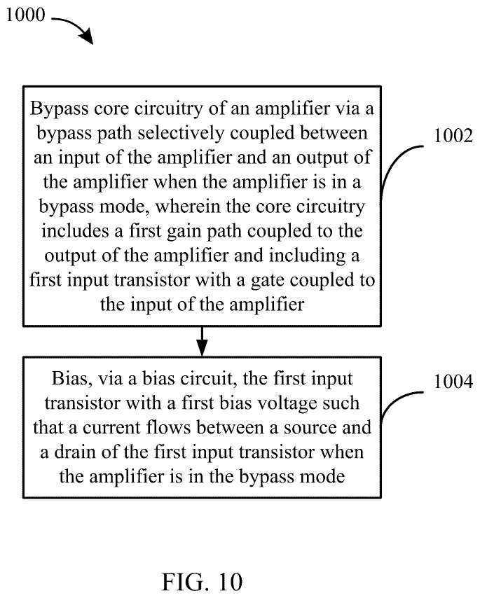

FIG. 10 is a flow diagram illustrating example operations 1000 for signal amplification, in accordance with certain aspects of the present disclosure. The operations 1000 may be performed, for example, by an amplifier, such as the LNA 400 of FIGS. 4-6 or the LNA 800 of FIGS. 8-9.

At block 1002, the amplifier may bypass one or more gain paths of the amplifier via a bypass path (e.g., bypass path 438) coupled between an input (e.g., one of Input 1 to Input n of FIG. 6 or the input shown in FIG. 9) of the amplifier and an output (e.g., RFOUT) of the amplifier when the amplifier is in a bypass mode. The one or more gain paths may include a first gain path (e.g., gain path 402) coupled to the output of the amplifier. The first gain path may include a first input transistor (e.g., input transistor 408) with a gate coupled to the input of the amplifier. In some aspects, the one or more gain paths may also include a first cascode transistor (e.g., cascode transistor 414) coupled in cascode with the first input transistor. In some aspects, at least one of the first input transistor or the first cascode transistor comprises a floating-body-type transistor. In some aspects, bypassing the one or more gain paths include closing one or more series switches of the bypass path.

At block 1004, the amplifier may bias, via a bias circuit (e.g., bias circuit 700 of FIG. 7), the first input transistor with a first bias voltage (e.g., 0.2 V as shown in FIG. 6 or 1.2 V as shown in FIG. 9) and the first cascode transistor with a second bias voltage (e.g., 0.6 V as shown in FIG. 6 or 0.2 V as shown in FIG. 9) such that a current flows between a source and a drain of the first input transistor when the amplifier is in the bypass mode. In some aspects, the amplifier may bias, via the bias circuit, the first cascode transistor with a second bias voltage (e.g., 0.6 V as shown in FIG. 6 or 0.2 V as shown in FIG. 9) such that the current flows between the source and the drain of the first input transistor when the amplifier is in the bypass mode.

In some aspects, the amplifier may bias the first input transistor with a third bias voltage (e.g., 0.4 V as shown in FIG. 4) and the first cascode transistor with a fourth bias voltage (e.g., 0.7 V as shown in FIG. 4) during an active mode of the amplifier. The third bias voltage may be greater than the first bias voltage, and the fourth bias voltage may be greater than the second bias voltage.

The one or more gain paths may also include a second gain path (e.g., gain path 404) coupled to the output of the amplifier. The second gain path may include a second input transistor (e.g., input transistor 410) with a gate coupled to the input of the amplifier and a second cascode transistor (e.g., cascode transistor 416) coupled in cascode with the second input transistor. The amplifier may also bias the second input transistor with the first bias voltage when the amplifier is in the bypass mode.

In some aspects, the amplifier performs input matching via an inductive element (e.g., inductive element 417) coupled between the input of the amplifier and the gate of the first input transistor. The bypass path may be coupled to a node (e.g., node 439 of FIG. 4) between the inductive element and the input of the amplifier. The bypass path may be coupled to a node (e.g., node 820 of FIG. 8) between the inductive element and the gate of the first input transistor.

In some aspects, the bias circuit includes a current mirror having a first current mirror transistor (e.g., transistor 704 of FIG. 7) and a second current mirror transistor (e.g., transistor 702), a gate of the first current mirror transistor being coupled to a gate of the second current mirror transistor and a drain of the first current mirror transistor. The current mirror may also include a second cascode transistor (e.g., cascode transistor 708) coupled in cascode with the first current mirror transistor and a third cascode transistor (e.g., cascode transistor 706) coupled in cascode with the second current mirror transistor. The bias circuit may be configured to generate the first bias voltage for the first input transistor at a drain of the first current mirror transistor. The bias circuit may also include an operational amplifier (e.g., amplifier 712) having a first input coupled to a drain of the second cascode transistor, a second input coupled to a Vref node, and an output coupled to gates of the second cascode transistor and the third cascode transistor. The bias circuit may be configured to generate the second bias voltage for the first cascode transistor at the output of the operational amplifier.

### Example Aspects

In addition to the various aspects described above, specific combinations of aspects are within the scope of the present disclosure, some of which are detailed below:

Aspect 1: An amplifier comprising: a first gain path coupled between an input of the amplifier and an output of the amplifier, wherein the first gain path comprises a first input transistor with a gate coupled to the input of the amplifier; a bypass path selectively coupled between the input of the amplifier and the output of the amplifier and configured to bypass at least the first input transistor of the first gain path in a bypass mode; and a bias circuit configured to bias the first input transistor with a first bias voltage at a level that causes a current to flow between a source and a drain of the first input transistor when the amplifier is in the bypass mode.

Aspect 2: The amplifier of Aspect 1, wherein: the first gain path further comprises a first cascode transistor coupled in cascode with the first input transistor; and the bias circuit is further configured to bias the first cascode transistors with a second bias voltage such that the current flows between the source and the drain of the first input transistor when the amplifier is in the bypass mode.

Aspect 3: The amplifier of Aspect 1 or 2, wherein the first input transistor comprises a floating-body-type transistor.

Aspect 4: The amplifier according to any of Aspects 1-3, wherein the bypass path includes one or more series switches configured to be closed in the bypass mode.

Aspect 5: The amplifier according to any of Aspects 1-4, wherein the bias circuit is configured to bias the first input transistor with a third bias voltage during an active mode of the amplifier.

Aspect 6: The amplifier of Aspect 5, wherein the third bias voltage is greater than the first bias voltage.

Aspect 7: The amplifier according to any of Aspects 1-6, wherein: the amplifier further comprises a second gain path coupled to the output of the amplifier; the second gain path comprises a second input transistor with a gate coupled to the input of the amplifier; and the bias circuit is configured to bias the second input transistor with the first bias voltage when the amplifier is in the bypass mode.

Aspect 8: The amplifier according to any of Aspects 1-7, further comprising an inductive element coupled between the input of the amplifier and the gate of the first input transistor.

Aspect 9: The amplifier of Aspect 8, wherein the bypass path is coupled to a node between the inductive element and the input of the amplifier.

Aspect 10: The amplifier of Aspect 8 or 9, wherein the bypass path is coupled to a node between the inductive element and the gate of the first input transistor.

Aspect 11: The amplifier according to any of Aspects 1-10, wherein the bias circuit comprises: a current mirror having a first current mirror transistor and a second current mirror transistor, a gate of the first current mirror transistor being coupled to a gate of the second current mirror transistor and a drain of the first current mirror transistor; a first cascode transistor coupled in cascode with the first current mirror transistor; and a second cascode transistor coupled in cascode with the second current mirror transistor, wherein the bias circuit is configured to generate the first bias voltage for the first input transistor at a drain of the first current mirror transistor.

Aspect 12: The amplifier of Aspect 11, wherein: the first gain path further comprises a third cascode transistor coupled in cascode with the first input transistor; the bias circuit further comprises an operational amplifier having a first input coupled to a drain of the first cascode transistor, a second input coupled to a reference voltage (Vref) node, and an output coupled to gates of the first cascode transistor and the second cascode transistor; and the bias circuit is configured to generate a second bias voltage for the third cascode transistor at the output of the operational amplifier.

Aspect 13: The amplifier according to any of Aspects 1-12, further comprising a control circuit configured to apply one or more control signals operative to activate the bypass path and provide the first bias voltage to the first input transistor.

Aspect 14: The amplifier according to any of Aspects 1-13, wherein the level of the first bias voltage is configured to pre-bias the first input transistor.

Aspect 15: A method for signal processing, comprising: bypassing one or more gain paths of an amplifier via a bypass path selectively coupled between an input of the amplifier and an output of the amplifier when the amplifier is in a bypass mode, wherein the one or more gain paths include a first gain path coupled to the output of the amplifier and including a first input transistor with a gate coupled to the input of the amplifier; and biasing, via a bias circuit, the first input transistor with a first bias voltage such that a current flows between a source and a drain of the first input transistor when the amplifier is in the bypass mode.

Aspect 16: The method of Aspect 15, wherein: the one or more gain paths further include a first cascode transistor coupled in cascode with the first input transistor; and the method further comprises biasing the first cascode transistor with a second bias voltage such that a current flows between a source and a drain of the first input transistor when the amplifier is in the bypass mode.

Aspect 17: The method of Aspect 15 or 16, wherein at least one of the first input transistor comprises a floating-body-type transistor.

Aspect 18: The method of Aspect 16 or 17, wherein bypassing the one or more gain paths include closing one or more series switches of the bypass path.

Aspect 19: The method according to any of Aspects 15-18, further comprising biasing the first input transistor with a third bias voltage during an active mode of the amplifier.

Aspect 20: The method of Aspect 19, wherein the third bias voltage is greater than the first bias voltage.

Aspect 21: The method according to any of Aspects 15-20, wherein: the one or more gain paths further comprise a second gain path coupled to the output of the amplifier; the second gain path comprises a second input transistor with a gate coupled to the input of the amplifier and a second cascode transistor coupled in cascode with the second input transistor; and the method further comprises biasing the second input transistor with the first bias voltage when the amplifier is in the bypass mode.

Aspect 22: The method according to any of Aspects 15-21, further comprising performing input matching via an inductive element coupled between the input of the amplifier and the gate of the first input transistor.

Aspect 23: The method of Aspect 22, wherein the bypass path is coupled to a node between the inductive element and the input of the amplifier.

Aspect 24: The method of Aspect 22 or 23, wherein the bypass path is coupled to a node between the inductive element and the gate of the first input transistor.

Aspect 25: A wireless device comprising: an antenna; and an amplifier having an input coupled to the antenna, wherein the amplifier comprises: a gain path coupled to between the input of the amplifier and an output of the amplifier, wherein the gain path comprises an input transistor with a gate coupled to the input of the amplifier; a bypass path selectively coupled between the input of the amplifier and the output of the amplifier; a bias circuit configured to bias the input transistor; and a control circuit configured to provide one or more control signals to the amplifier that enable the bypass path in a bypass mode and provide a first bias voltage to the input transistor at a level that causes a current to flow between a source and a drain of the input transistor during the bypass mode.

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An amplifier comprising:
a first gain path coupled between an input of the amplifier and an output of the amplifier, wherein the first gain path comprises a first input transistor with a gate coupled to the input of the amplifier;
a bypass path selectively coupled between the input of the amplifier and the output of the amplifier and configured to bypass at least the first input transistor of the first gain path in a bypass mode; and
a bias circuit configured to bias the first input transistor with a first bias voltage at a level that causes a current to flow between a source and a drain of the first input transistor when the amplifier is in the bypass mode.

2. The amplifier of claim 1, wherein:
the first gain path further comprises a first cascode transistor coupled in cascode with the first input transistor; and
the bias circuit is further configured to bias the first cascode transistors with a second bias voltage such that the current flows between the source and the drain of the first input transistor when the amplifier is in the bypass mode.

3. The amplifier of claim 1, wherein the first input transistor comprises a floating-body-type transistor.

4. The amplifier of claim 1, wherein the bypass path includes one or more series switches configured to be closed in the bypass mode.

5. The amplifier of claim 1, wherein the bias circuit is configured to bias the first input transistor with a third bias voltage during an active mode of the amplifier.

6. The amplifier of claim 5, wherein the third bias voltage is greater than the first bias voltage.

7. The amplifier of claim 1, wherein:
the amplifier further comprises a second gain path coupled to the output of the amplifier;
the second gain path comprises a second input transistor with a gate coupled to the input of the amplifier; and
the bias circuit is configured to bias the second input transistor with the first bias voltage when the amplifier is in the bypass mode.

8. The amplifier of claim 1, further comprising an inductive element coupled between the input of the amplifier and the gate of the first input transistor.

9. The amplifier of claim 8, wherein the bypass path is coupled to a node between the inductive element and the input of the amplifier.

10. The amplifier of claim 8, wherein the bypass path is coupled to a node between the inductive element and the gate of the first input transistor.

11. The amplifier of claim 1, wherein the bias circuit comprises:
a current mirror having a first current mirror transistor and a second current mirror transistor, a gate of the first current mirror transistor being coupled to a gate of the second current mirror transistor and a drain of the first current mirror transistor;
a first cascode transistor coupled in cascode with the first current mirror transistor; and
a second cascode transistor coupled in cascode with the second current mirror transistor, wherein the bias circuit is configured to generate the first bias voltage for the first input transistor at a drain of the first current mirror transistor.

12. The amplifier of claim 11, wherein:
the first gain path further comprises a third cascode transistor coupled in cascode with the first input transistor;
the bias circuit further comprises an operational amplifier having a first input coupled to a drain of the first cascode transistor, a second input coupled to a reference voltage (Vref) node, and an output coupled to gates of the first cascode transistor and the second cascode transistor; and
the bias circuit is configured to generate a second bias voltage for the third cascode transistor at the output of the operational amplifier.

13. The amplifier of claim 1, further comprising a control circuit configured to apply one or more control signals operative to activate the bypass path and provide the first bias voltage to the first input transistor.

14. The amplifier of claim 1, wherein the level of the first bias voltage is configured to pre-bias the first input transistor.

15. A method for signal processing, comprising:
bypassing one or more gain paths of an amplifier via a bypass path selectively coupled between an input of the amplifier and an output of the amplifier when the amplifier is in a bypass mode, wherein the one or more gain paths include a first gain path coupled to the output of the amplifier and including a first input transistor with a gate coupled to the input of the amplifier; and
biasing, via a bias circuit, the first input transistor with a first bias voltage such that a current flows between a source and a drain of the first input transistor when the amplifier is in the bypass mode.

16. The method of claim 15, wherein:
the one or more gain paths further include a first cascode transistor coupled in cascode with the first input transistor; and
the method further comprises biasing the first cascode transistor with a second bias voltage such that a current flows between a source and a drain of the first input transistor when the amplifier is in the bypass mode.

17. The method of claim 15, further comprising biasing the first input transistor with a third bias voltage during an active mode of the amplifier.

18. The method of claim 15, wherein:
the one or more gain paths further comprise a second gain path coupled to the output of the amplifier;
the second gain path comprises a second input transistor with a gate coupled to the input of the amplifier and a second cascode transistor coupled in cascode with the second input transistor; and
the method further comprises biasing the second input transistor with the first bias voltage when the amplifier is in the bypass mode.

19. The method of claim 15, further comprising performing input matching via an inductive element coupled between the input of the amplifier and the gate of the first input transistor.

20. A wireless device comprising:
an antenna; and
an amplifier having an input coupled to the antenna, wherein the amplifier comprises:
a gain path coupled between the input of the amplifier and an output of the amplifier, wherein the gain path comprises an input transistor with a gate coupled to the input of the amplifier;
a bypass path selectively coupled between the input of the amplifier and the output of the amplifier;
a bias circuit configured to bias the input transistor; and
a control circuit configured to provide one or more control signals to the amplifier that enable the bypass path in a bypass mode and provide a first bias voltage to the input transistor at a level that causes a current to flow between a source and a drain of the input transistor during the bypass mode.
